(19) United States
(12) Patent Application Publication
(10) Pub. No.: US 2018/0218920 A1
(43) Pub. Date: Aug. 2, 2018

(54) GRAPHITE HEAT SINK

(71) Applicant: Panasonic Intellectual Property Management Co., Ltd., Osaka (JP)

(72) Inventors: RYOU KUWABARA, Osaka (JP); NAOMI NISHIKI, Kyoto (JP); HIDETOSHI KITAURA, Osaka (JP); ATSUSHI TANAKA, Osaka (JP); TAKESHI NISHIKAWA, Osaka (JP)

(21) Appl. No.: 15/866,018

(22) Filed: Jan. 9, 2018

(30) Foreign Application Priority Data
Feb. 2, 2017 (JP) 2017-017839

(51) Int. Cl. H01L 21/48; B32B 3/14; B32B 9/00; B32B 7/12; B23K 1/00; F28F 21/02; H01L 23/373

(52) U.S. Cl. CPC H01L 21/4882; B32B 3/14; B32B 9/007; B32B 7/12; B32B 2457/14; F28F 21/02; H01L 23/3735; B32B 2307/302; B23K 1/0008

(57) ABSTRACT

A graphite heat sink that is light in weight, excellent in thermal conductivity and high in mechanical strength. A graphite heat sink includes two or more graphite joined plates and solder joining layers which are alternately stacked, in which each graphite joined plate includes plural pieces of graphite plates and a solder joining portion, surfaces of the plural pieces of graphite plates parallel to a thickness direction and the solder joining portion are joined to one another, and the solder joining layer and the solder joining portion are formed of the same solder material.

### TECHNICAL FIELD

The technical field relates to a graphite heat sink used for high thermal conduction applications such as a heat spreader for an LSI chip and a heat sink of for semiconductor power module.

### BACKGROUND

Carbon materials attract attention as materials for a heat sink used as a heat spreader for an LSD chip, a heat sink for a semiconductor power module because the carbon materials have thermal conductivity equivalent to aluminum and copper which are common high-thermal conductive materials and furthermore have better thermal dispersion characteristics than copper. As a related-art heat sink using carbon material, for example, there is a heat sink whose mechanical strength is improved by coating a metal sealing material over compressively solidified brittle carbon particles, as shown in JP-A-2012-195467 (Patent Literature 1).

The sealing material used for the heat sink of Patent Literature 1 has the thermal conductivity equivalent to carbon materials as it is made of aluminum or copper. However, the material is thick, that is, 0.1 to 2 mm in thickness, and the material covers the carbon material in a hermetic manner, therefore, the entire heat sink is heavy. Moreover, carbon having a high thermal conductivity does not exist on the surface, therefore, thermal conduction in a planar direction is not increased. Furthermore, a device for forming a metal sealing material such as a metal mold is necessary, which increases manufacturing costs.

### SUMMARY

An objective thereof is to provide a graphite heat sink that is light in weight, excellent in thermal conductivity and high in mechanical strength.

In order to achieve the above objective, a graphite heat sink according to the technical field includes two or more graphite joined plates and solder joining layers which are alternately stacked, in which each graphite joined plate includes plural pieces of graphite plates and a solder joining portion, and surfaces of the plural pieces of graphite plates parallel to a thickness direction and the solder joining portion are joined to one another. The solder joining layer and the solder joining portion may be formed of the same solder material. The number of solder joining layers may be one layer less than the number of the graphite joined plates. Moreover, two graphite joined plates adjacent in a stacked order may have different numbers of graphite plates to thereby reduce portions where respective solder joining portions overlap each other at places other than a peripheral edge portion through the solder joining layer. A thickness of the solder joining layer and a thickness of the solder joining portion may be equal to or more than 0.05 mm and equal to or less than 0.5 mm. Furthermore, the solder material may contain at least one kind of element capable of forming a compound with tin (Sn) and carbon (C) and may contain tin (Sn) as the remainder.

According to the technical field, it is possible to provide a graphite heat sink that is light in weight and excellent in thermal conductivity and mechanical strength, which is suitable for the increase in size.

### BRIEF DESCRIPTION OF THE DRAWINGS

FIG. 1 is a schematic view showing a graphite heat sink according to an embodiment of the technical field;

FIG. 2 is a cross-sectional view taken along A-A′ of the graphite heat sink of FIG. 1;

FIG. 3 is an exploded perspective view seen from above the graphite heat sink according to an embodiment;

FIG. 4A is an explanatory view of a joining method for a solder joining layer and a solder joining portion according to an embodiment;

FIG. 4B is an explanatory view of the joining method for the solder joining layer and the solder joining portion according to an embodiment; and

FIG. 5 is a schematic view showing a device for evaluation tests for thermal conductivity and flexibility in Examples and Comparative Examples.

### DESCRIPTION OF EMBODIMENTS

Hereinafter, an embodiment of the technical field will be explained with reference to the drawings.

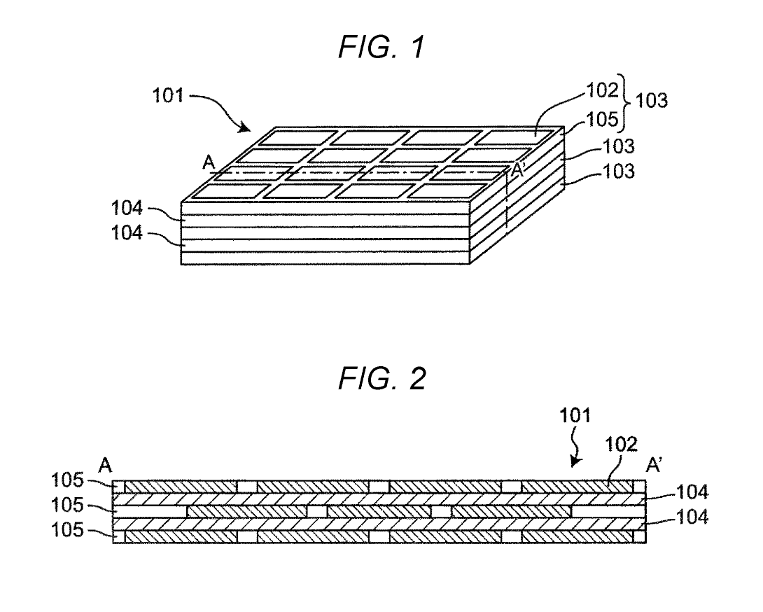

FIG. 1 is a schematic view showing a graphite heat sink according to an embodiment of the technical field. A graphite heat sink 101 has a structure in which three graphite joined plates 103 (hereinafter also referred to as merely joined plates 103) and two solder joining layers 104 are alternately stacked. The number of graphite joined plates 103 is not particularly limited and may be suitably selected in accordance with a space, necessary heat transport ability and the like, however, two or more and five or less plates are preferable. The joined plate 103 is formed by including plural pieces of graphite plates 102 and a solder joining portion 105. Here, surfaces of the plural pieces of graphite plates 102 parallel to a thickness direction and the solder joining portion 105 are joined to one another. Moreover, the three joined plates 103 are joined to one another by the solder joining layers 104. The graphite heat sink 101 having the above structure does not contain a metal material other than a solder material for joining, therefore, reduction of weight to a mass of approximately ⅓ of a related-art heat sink is achieved. As a size can be controlled freely by changing the number of the graphite plates 102 used for the joined plate 103, the graphite heat sink 101 size can be extremely varied. Accordingly, large-scale reduction of weight and improvement of thermal conductivity of the heat sink can be expected in heat dissipation applications such as heat sinks inside large electronic devices or heat sinks for IGBT, which are currently addressed only by metal plates. A graphite material can be also used for large area applications, which are not limited to an ICT field like in the past. A solder material which is the same as a material used for the solder joining portions 105 is used for the solder joining layers 104. As the same solder material is used for the solder joining layers 104 and the solder joining portions 105, the joint is firm and contributes to an improvement in mechanical strength of the graphite heat sink 101.

Furthermore, the number of the solder joining layers 104 alternately stacked with the joined plates 103 is one layer less than the number of the joined plates 103, therefore, both surfaces of the graphite heat sink 101 are formed by the joined plates 103. Accordingly, the thermal conductivity in the planer direction can be further improved and the surface is not easily oxidized as exposure of the metal material is reduced. As a result, the graphite heat sink 101 will have a long lifetime.

FIG. 2 is a cross-sectional view taken along A-A′ of the graphite heat sink of FIG. 1. In three joined plates 103 of the graphite heat sink 101 of FIG. 1, two pieces of joined plates 103 adjacent in a stacked order have different numbers of graphite plates 102, therefore, respective solder joining portions 105 do not overlap one another through the solder joining layer 104 on an A-A′ cross section except for a peripheral edge portion 106. When the two pieces of joined plates 103 adjacent in the stacked order have different numbers of graphite plates 102 as described above, portions where the solder joining portions 105 overlap each other through the solder joining layer 104 at places other than the peripheral edge portion are reduced. In the specification, the “reduction” of portions where the solder joining portions 105 overlap each other through the solder joining layer 104 at places other than the peripheral edge portion means that a percentage of portions in the surface area of the solder joining portion 105 overlapping another solder joining portion 105 through the solder joining layer 104 is equal to or less than 80%. For example, when the two pieces of joined plates 103 adjacent in the stacked order have the same number of graphite plates 102, that is, when two pieces of the solder joining portions 105 having the same shape with the same number of holes are used, the percentage of portions in the surface area of the solder joining portion 105 overlapping another solder joining portion 105 through the solder joining layer 104 will be 100%. Portions where the solder joining portion 105 overlap each other through the solder joining layer 104 as in the peripheral edge portions in FIG. 2 are low in strength and thermal conductivity as compared with portions where the solder joining portion 105 overlaps the graphite plates 102 through the solder joining layer 104 and portions where the graphite plates 102 overlap each other through the solder joining layer 104. Therefore, as the portions where the solder joining portions 105 overlap each other through the solder joining layer 104 at places other than the peripheral edge portion are reduced, mechanical strength of the graphite heat sink 101 is improved and thermal conductivity in the planer direction perpendicular to the thickness direction is improved. Furthermore, in three joined plates 103 of the graphite heat sink 101, two pieces of joined plates 103 adjacent in the stacked order have different numbers of graphite plates 102, respective graphite plates 102 can disperse stress evenly with respect to variation in thermal expansion due to melting and solidification of solder, which leads to another effect: peeling or chipping of the graphite plates 102 can be suppressed.

A thickness of the solder joining layer 104 and the solder joining portion 105 may be 0.01 mm or more and 0.5 mm or less, and are preferably 0.01 mm or more and 0.1 mm or less. When the thicknesses of the solder joining layer 104 and the solder joining portion 105 are within the above range, not only variations in thickness of the graphite heat sink 101 are reduced but also variation of in thermal expansion due to melting and solidification of solder can be reduced, therefore, deformation of the graphite heat sink 101 can be also reduced.

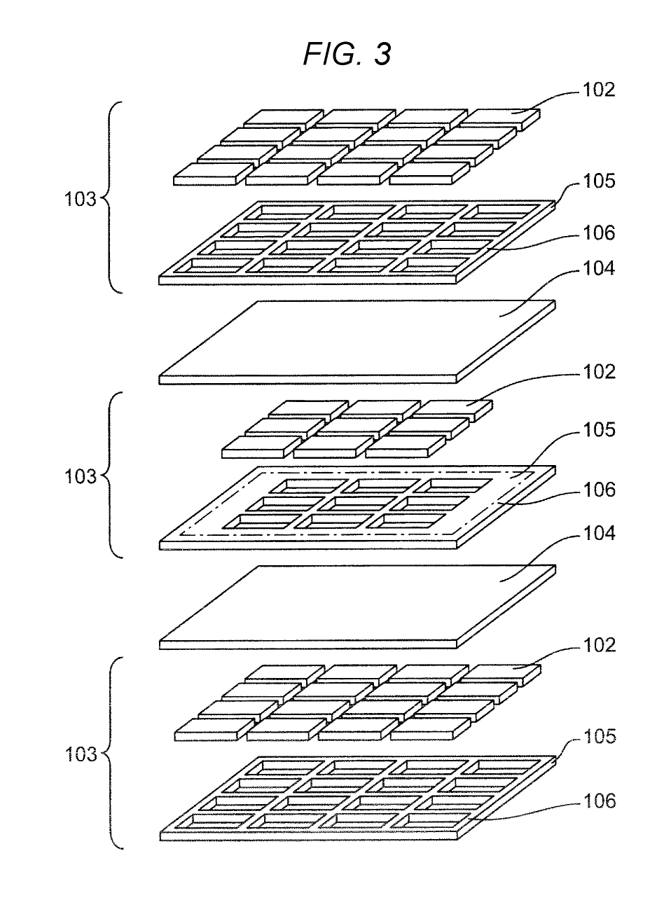

FIG. 3 is an exploded perspective view seen from above the graphite heat sink 101.

### (Graphite Joined Plate 103)

Two of the three pieces of graphite joined plates 103 forming the graphite heat plate 101 of FIG. 3 form an upper surface and a lower surface of the graphite heat sink 101. The graphite joined plate 103 is formed by plural graphite plates 102 and the solder joining portion 105. The solder joining portion 105 has the peripheral edge portion 106 at a place where a distance to an outer edge is equal to or less than 1 mm, preferably equal to or less than 0.5 mm. The solder joining portion 105 has holes into which the graphite plates 102 forming the joined plate 103 fit. A width of a lattice-shaped portion between a hole and an adjacent hole is preferably equal to or more than 0.5 mm and equal to or less than 1 mm. When a width of the lattice-shaped portion between holes is equal to or more than 0.5 mm, mechanical strength of the graphite heat sink 101 can be increased. Moreover, when the width is equal to or less than 1 mm, excessive solder material is not used and the graphite heat sink 101 can be reduced in weight. While a structure body obtained by fitting the graphite plates 102 into the holes of the solder joining portion 105 is pressed at a pressure of 5 g/cm² or more to 10 g/10 cm² or less, the structure body is increased to a melting temperature of the solder material used for the solder joining portion 105, then, cooled to thereby form the joined plate 103.

### (Graphite Plate 102)

The graphite plates 102 can use materials containing a carbon component on the surface, for example, can use a pressurized laminate of a high orientation graphite sheet, an adhesive laminate of the high-orientation graphite sheet, an expanded graphite sheet and so on. However, materials are not limited to the above. A thermal conductivity of the graphite plates 102 is preferably 100 W/m·K or more. As the graphite plates 102 have such thermal conductivity, the graphite heat sink 101 manufactured from the graphite plates 102 can be effectively used as a heat spreader. The shape of the graphite plate 102 is not particularly limited and an arbitrary shape can be used. For example, a plate-shaped solid as shown in FIG. 3, curable liquid and so on may be used. The graphite plate 102 having an arbitrary dimension may be used in consideration of a size of a furnace used when a joined body is fabricated. For example, a depth may be 200 mm or less, a width may be 200 mm or less and a height may be 0.01 to 1 mm.

### (Solder Joining Layer 104, Solder Joining Portion 105)

The solder joining portion 105 and the solder joining layer 104 are formed of the same solder material. An arbitrary alloy may be used for the solder material forming the solder joining portion 105 and the solder joining layer 104. It is preferable to use an alloy containing at least one kind of element capable of forming a compound with tin (Sn) and carbon (C) and containing tin (Sn) as the remainder (hereinafter also referred to as merely a carbon joining material). As the remainder of the carbon joining material, titanium (Ti) or the like may be contained in addition to tin (Sn). It is also preferable that an upper surface of the solder joining layer 104 has substantially the same size as an upper surface of the joined plate 103, namely, a portion surrounded by an outer edge of the solder joining portion 105.

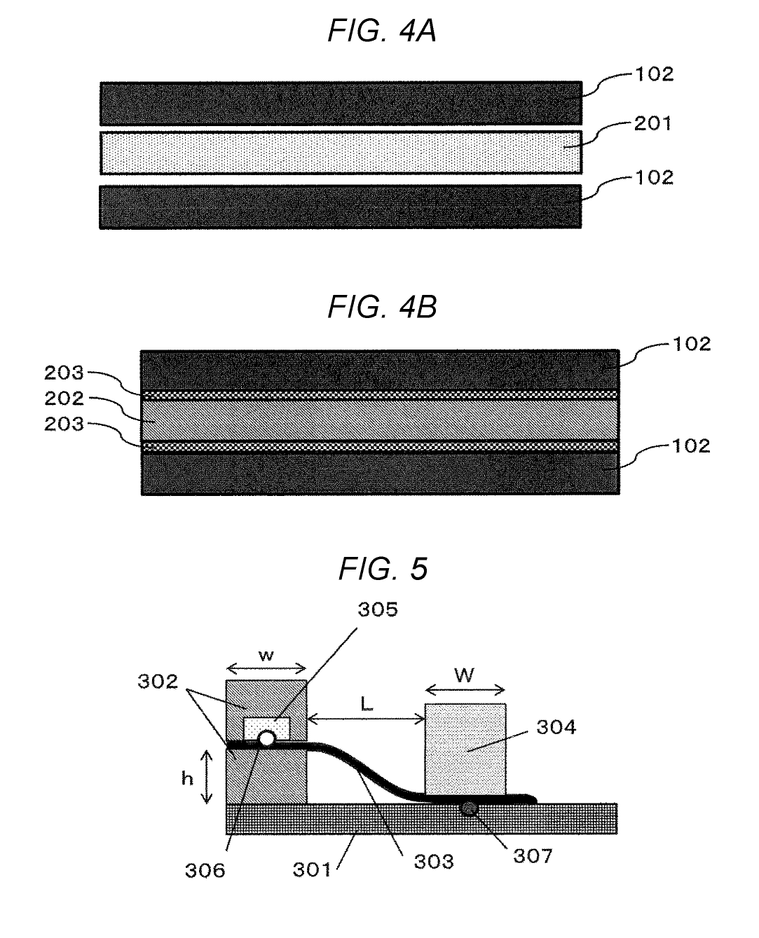

FIG. 4A and FIG. 4B show a joining method adopted when the carbon joining material is used for the solder joining layer 104 and the solder joining portion 105. FIG. 4A shows the graphite plates 102 before joining and a carbon joining material 201 forming the solder joining layer 104 or the solder joining portion 105. While two pieces of graphite plates 102 and the carbon joining material 201 sandwiched therebetween are pressed, a temperature thereof is increased to a melting temperature of the carbon joining material 201, then, they are cooled, thereby joining two pieces of graphite plates 102 to each other as shown in FIG. 4B. As shown in FIG. 4B, a carbon joining structure portion 202 and carbon compound layers 203 are formed on an interface between the graphite plates 102. The carbon compound layer 203 is a layer of a compound containing at least one kind of element capable of forming a compound with tin and carbon, and containing tin and carbon. Accordingly, the solder joining layer 104, the joining portion 105 and the graphite plates 102 are joined by the carbon compound layer 203 extremely firmly at an atomic level. Therefore, strength of the joined plate 103 or the heat sink 101 can be increased. As the carbon compound layers 203 exist, a difference in thermal conductivity at an interface between the solder joining layer 104, the solder joining portion 105 and the graphite plates 102 can be reduced, thereby increasing strength of the graphite heat sink 101. Furthermore, a thickness of a layer containing metal can be reduced by using the carbon joining material, therefore, the graphite heat sink 101 can be reduced in weight.

The graphite heat sink according to the technical field was fabricated as shown by the following Examples 1 to 4.

### Example 1

The graphite plates 102 formed of the pressurized laminate of high orientation graphite, each having a depth 200 mm, a width 200 mm and a height 0.2 mm were prepared. Moreover, the solder joining portion 105 made of the carbon joining material, having holes with a depth 200 mm and a width 200 mm and the peripheral edge portion 106 as a portion in which the distance to the outer edge is 1 mm or less was prepared, and 16 pieces of graphite plates 102 in the prepared graphite plates 102 are fitted into the solder joining portion 105 to form a structure body. While the structure body was pressed at a pressure of 5 g/cm², the structure body was heated to a melting point of the solder material forming the solder joining portion 105, then, cooled to thereby form the joined plate 103. Ten pieces of similar joined plates 103 were formed by using graphite plates 102. Five pieces of joined plates 103 including 16 pieces of graphite plates 102 and 5 pieces of joined plates 103 including 9 pieces of graphite plates 102 were respectively formed to obtain a total sum of 10 pieces of joined plates 103. The 10 pieces of joined plates 103 and 9 pieces of solder joining layers made of the carbon joining material were stacked alternately as well as so that two graphite joined plates adjacent 103 in the stacked order in the 10 pieces of joined plates 103 have different numbers of graphite plates 102 to thereby form a laminated body. The laminated body was heated to 550 degrees while being pressed at a pressing pressure whereby a sum of thicknesses of the carbon joining structure portion 202 and the carbon compound layers 203 which are adjacent to each other was 0.01 mm. The laminated body was kept heated for 10 minutes, then, naturally cooled to thereby fabricate the graphite heat sink 101 with a thickness of 2 mm. As the solder joining layers 104 and the solder joining portions 105, a carbon joining material obtained by processing an alloy with a composition containing 0.1 wt % of titanium and tin as the remainder in a foil state. The used solder joining layer 104 and the solder joining portion 105 had the same sizes, which were a depth 80.25 cm and a width 80.25 cm. The height of the solder joining layer 104 were 0.01 mm and the solder joining portion 105 was 0.02 mm so as to correspond to the height of the graphite plates 102.

### Example 2

The graphite heat sink 101 was fabricated in the same conditions as Example 1 except that a high-orientation graphite adhesive laminate having the same size was used instead of the graphite plates 102.

### Example 3

The graphite heat sink 101 was fabricated in the same conditions as Example 1 except that an expanded graphite sheet having the same size was used instead of the graphite plates 102.

### Example 4

The graphite heat sink 101 was fabricated in the same conditions as Example 1 except that a total sum of joined plates to be stacked was 20 pieces, in which 10 pieces of joined plates including 9 pieces of graphite plates 102 and 10 pieces of joined plates including 16 pieces of graphite plates 102 were formed.

### Example 5

The graphite heat sink 101 was fabricated in the same conditions as Example 1 except that a thickness of the joining layer 104 was 0.1 mm.

Furthermore, graphite heat sinks for comparison were fabricated as shown in the following comparative examples 1 to 4.

### Comparative Example 1

The pressurized laminate of high orientation graphite used in Example 1 was formed to have a depth 200 mm, a width 200 mm and a height 0.2 mm, thereby fabricating the graphite heat sink.

### Comparative Example 2

All joined plates 103 were fabricated so as to include 9 pieces of graphite plates and a laminated body in which the solder joining portions 105 of the two joining plates 103 adjacent in the stacked order overlap at most parts through the solder joining layer 104 is fabricated by using the joined plates to thereby fabricate the graphite heat sink in the same conditions as Example 1 except for the above conditions.

### Comparative Example 3

The graphite heat sink was fabricated in the same conditions as Example 1 except that a thickness of the joining layer 104 was 0.5 mm.

### Comparative Example 4

The joined plate 103 was formed without providing a peripheral end portion so that the graphite plates are exposed on surfaces parallel to a thickness direction, and the graphite heat sink was fabricated in the same conditions as Example 1 except for the above condition.

Next, evaluations for thermal conductivity and mechanical strength of the fabricated graphite heat sinks were performed by the following procedures.

Samples fabricated in Examples and Comparative Examples were cut out into a size of 40 mm depth and a 10 mm width, and evaluation tests for thermal conductivity and flexibility were performed. The size of the cut-out samples was determined by estimating the shape at the time of being arranged on a substrate as a heat spreader. FIG. 5 is a schematic view showing evaluation tests for thermal conductivity and flexibility in Examples and Comparative Examples. A joined body sample 303 fixed to a flat plate 301 by using a fixing jig 302 was pressed onto the flat surface 301 by a pressor jig 304 and evaluation was performed. A heat generating body 305 exists at an upper part of the fixing jig 302, and temperatures were measured by a thermocouple 306 for measuring input temperatures at an interface between the heat generating body 305 and the joining body sample 303. In the evaluations, the temperature control of the heat generating body was performed so that the temperature of the thermocouple 306 for measuring input temperatures reached 55° C. A temperature of the joining body sample 303 increased by heat transmission from the heat generating body 305 was measured by a thermocouple 307 for measuring transmitted temperatures, and the temperature was determined as a transmitted temperature. Thermal conductivity was evaluated by calculating a difference between the transmitted temperature and the input temperature. The tests were performed while cooling the presser jigs 304 at a flow rate of 1 liter per a minute by using water of 25° C.

The fixing jig 302 with a width “w” of 10 mm, a depth of 10 mm and a height “h” of 2 mm was used. The presser jig 304 with a width “W” of 10 mm, a depth of 10 mm and a height of 15 mm was used. A distance “L” between an end of the fixing jig 302 and an end of the pressure jig 304 was 15 mm.

The heat generating body 305 with a 5 mm width and a 3 mm height was used, which was installed in a center of a lower surface of the upper fixing jig 302. The thermocouple 306 for measuring input temperatures was installed on the surface of the center of the lower surface of the heat generating body 305. The thermocouple 307 for measuring transmitted temperatures was installed so as to sandwich the joining body sample 303 between the center of a lower surface of the presser jig 304 and the thermocouple 307 for measuring transmitted temperatures.

Decision of thermal conductivity of the graphite heat sink is performed based on a lowering rate of thermal conductivity calculated from a temperature difference measured by performing the above test with respect to the high-orientation graphite in Comparative Example 1 in which the joining material such as solder is not used and a temperature difference of test results of respective examples. The lowering rate of thermal conductivity is a ratio of differences between a temperature difference of Example 1 and a temperature difference of Comparative Example 1 with respect to the temperature difference of the high-orientation graphite in Comparative Example 1, which is calculated as (12.7−12)/12×100=5.8%.

As for a rating criteria of thermal conductivity, when the ratio of the lowering rate in temperature differences with respect to the temperature difference of Comparative Example 1 is 10% or less, it is rated as “excellent”, a ratio of greater than 10% and less than 16% is “good” and a ratio of 16% or more is rated as “poor”. When the rating is “excellent”, the sample has a sufficient heat dissipation property at the time of being used for a product as a heat dissipation member and performance of a CPU is not reduced. When the rating is “good”, temperature increase occurs though the performance of the CPU is not reduced. When the rating is “poor”, it is difficult to dissipate the heat generation, and therefore, the CPU is stopped. As for a rating criteria of mechanical strength, cross-section observation is performed after the evaluation of thermal conductivity. A case where there is no crack in the carbon joining structure portion 202 and the carbon compound layer 203 is rated as “good” and a case where there is a crack is rated as “poor”.

Results obtained by performing the above-described evaluations for thermal conductivity and mechanical strength with respect to Examples and Comparative Examples according to the application of the technical field are shown in Table 1. In Table 1, a case where two graphite joined plates adjacent in the stacked order have the same number of graphite plates and thus respective solder joining portions overlap each other for the most part at places other than the peripheral edge portion through the solder joining layer is represented as “overlapping”, and a case where two graphite joined plates have different numbers of graphite plates and thus portions where the respective solder joining portions overlap each other at places other than the peripheral edge portion through the solder joining layer are reduced is represented as “not overlapping”. Furthermore, a case where the graphite plate is exposed on a surface parallel to the thickness direction of the joined plate 103 is represented as “exposed” and a case where the graphite plate is not exposed is represented as “not exposed”.

TABLE 1

| | | | | Positional | |
|---|---|---|---|---|---|
| | | | | relation | |
| | | | | between joining | |
| | | Number | Thickness | portions of | Exposure |
| | | of heat | of joining | joined plates | at side |
| | | sinks | layer | adjacent in | surface of |
| | Carbon material | (pieces) | (mm) | staked order | graphite |
| Example 1 | Pressurized laminate of | 10 | 0.01 | Not overlapping | Not exposed |
| | high-orientation graphite | | | | |
| Example 2 | Adhesive laminate of high- | 10 | 0.01 | Not overlapping | Not exposed |
| | orientation graphite | | | | |
| Example 3 | Expanded graphite sheet | 10 | 0.01 | Not overlapping | Not exposed |
| Example 4 | Pressurized laminate of | 20 | 0.01 | Not overlapping | Not exposed |
| | high-orientation graphite | | | | |
| Example 5 | Pressurized laminate of | 10 | 0.1 | Not overlapping | Not exposed |
| | high orientation graphite | | | | |
| Comparative | Pressurized laminate of | — | — | — | — |
| Example 1 | high-orientation graphite | | | | |
| Comparative | Pressurized laminate of | 10 | 0.01 | overlapping | Not exposed |
| Example 2 | high-orientation graphite | | | | |
| Comparative | Pressurized laminate of | 10 | 0.5 | Not overlapping | Not exposed |
| Example 3 | high-orientation graphite | | | | |
| Comparative | Pressurized laminate of | 10 | 0.01 | Not overlapping | Exposed |
| Example 4 | high-orientation graphite | | | | |

| | Temperature | Lowering | | |
|---|---|---|---|---|
| | difference | rate | Thermal | |
| | (° C.) | (%) | conductivity | Strength |
| Example 1 | 12.7 | 5.8 | Excellent | Good |
| Example 2 | 13.5 | 12.5 | Good | Good |
| Example 3 | 13.6 | 13 | Good | Good |
| Example 4 | 12.9 | 7.5 | Excellent | Good |
| Example 5 | 13.2 | 8.5 | Excellent | Good |
| Comparative | 12 | — | — | — |
| Example 1 | | | | |
| Comparative | 16 | 33.3 | Poor | Poor |
| Example 2 | | | | |
| Comparative | 17 | 41.7 | Poor | Poor |
| Example 3 | | | | |
| Comparative | — | — | — | — |
| Example 4 | | | | |

In Examples 1 to 5 as the embodiment of the technical field, the lowering rates of the thermal conductivity is lower than 16%, therefore, the graphite heat sink 101 with excellent thermal conductivity without reduction of performance of the CPU even when used for the heat dissipation member could be obtained. It is found that excellent thermal conductivity can be obtained particularly by using the pressurized laminate of high-orientation graphite in the graphite heat sink 101 according to the technical field from the lowering rates of thermal conductivity in Examples 1, 4 and 5. On the other hand, the lowering rate of thermal conductivity in Comparative Example 2 is 33.3%, which is drastically larger than 16% where the performance of the CPU begins to be reduced. This seems to be because thermal conduction in the planer direction perpendicular to the thickness direction was not increased as there were many portions where the solder joining portions 105 of the joined plates 103 adjacent in the stacked order overlap each other through the solder joining layer 104. Also in Comparative Example 3, the lowering rate of thermal conductivity is 41.7%, which is drastically larger than 16% where the performance of the CPU begins to be reduced. This seems to be because thermal conductivity in the thickness direction was reduced as the thicknesses of the solder joining portions 105 and the solder joining layer 104 were too large. In conditions of Comparative Example 4, the carbon joining material 201 used for the joining layer 104 and the joining portion 105 contracted and surface layers of the graphite plates 102 were peeled off due to the heating of the structure body, therefore, it was difficult to form the graphite heat sink 101.

The graphite heat sink according to the technical field can be used for an application of heat dissipation at heat generating parts in semiconductors, industrial apparatuses and so on.

What is claimed is:

1. A graphite heat sink comprising:
two or more graphite joined plates; and
solder joining layers which are alternately stacked,
wherein each graphite joined plate includes plural pieces of graphite plates and a solder joining portion, and
surfaces of the plural pieces of graphite plates parallel to a thickness direction and the solder joining portion are joined to one another.

2. The graphite heat sink according to claim 1,
wherein the solder joining layer and the solder joining portion are formed of the same solder material.

3. The graphite heat sink according to claim 1,
wherein the number of solder joining layers is one layer less than the number of the two or more graphite joined plates.

4. The graphite heat sink according to claim 1,
wherein two graphite joined plates adjacent in a stacked order in the two or more graphite joined plates have different numbers of graphite plates to thereby reduce portions where respective solder joining portions overlap each other at places other than a peripheral edge portion through the solder joining layer.

5. The graphite heat sink according to claim 1,
wherein a thickness of the solder joining layer and a thickness of the solder joining portion are equal to or more than 0.01 mm and equal to or less than 0.5 mm.

6. The graphite heat sink according to claim 1,
wherein the solder material contains at least one kind of element capable of forming a compound with tin (Sn) and carbon (C) and contains tin (Sn) as the remainder.

7. The graphite heat sink according to claim 1,
wherein a thickness of the solder joining layer and a thickness of the solder joining portion are equal to or more than 0.01 mm and equal to or less than 0.1 mm.

8. The graphite heat sink according to claim 1,
wherein the solder joining portion has a plurality of holes configured to receive the plural pieces of graphite plates, respectively,
wherein a width of a lattice-shaped portion between one of the plurality of holes and an adjacent hole is equal to or greater than 0.5 mm and equal to or less than 1 mm.
